(19) United States
(12) Patent Application Publication
(10) Pub. No.: US 2026/0194741 A1
(43) Pub. Date: Jul. 9, 2026

(54) FILTER UNIT

(71) Applicant: HAMAMATSU PHOTONICS K.K., Hamamatsu-shi, Shizuoka (JP)

(72) Inventors: Hiroki OYAMA, Shizuoka (JP); Katsumi SHIBAYAMA, Shizuoka (JP); Takafumi YOKINO, Shizuoka (JP); Takashi KASAHARA, Shizuoka (JP); Yumi KURAMOTO, Shizuoka (JP)

(21) Appl. No.: 19/133,719

(22) PCT Filed: Oct. 26, 2023
(86) PCT No.: PCT/JP2023/038714

§ 371 Date: May 29, 2025

(30) Foreign Application Priority Data
Dec. 1, 2022 (JP) 2022-192973

(51) Int. Cl. G02B 26/00; H05K 1/181

(52) U.S. Cl. CPC G02B 26/001; H05K 1/181

(57) ABSTRACT

A filter unit includes a support having a light passing portion; a Fabry-Perot interference filter including a pair of mirror sections facing each other in a first direction and having a variable distance from each other, the Fabry-Perot interference filter being disposed on the support so as to overlap the light passing portion when viewed from the first direction; and a wiring substrate disposed on the support so as not to overlap the Fabry-Perot interference filter when viewed from the first direction and electrically connected to the Fabry-Perot interference filter. A recessed portion is formed in the support with the first direction as a depth direction. The recessed portion reaches an outer edge of the support when viewed from the first direction. The wiring substrate is disposed in the recessed portion.

### TECHNICAL FIELD

The present disclosure relates to a filter unit including a Fabry-Perot interference filter.

### BACKGROUND ART

In order to configure a filter unit using a Fabry-Perot interference filter including a pair of mirror sections having a variable distance from each other, it is conceivable to use the following structure. That is, a CAN package includes a stem and a cap, a wiring substrate disposed on the stem in the CAN package, a Fabry-Perot interference filter disposed on the wiring substrate in the CAN package, and a plurality of lead pins penetrating the stem (refer to, for example, Patent Literature 1).

### CITATION LIST

### Patent Literature

Patent Literature 1: U.S. Unexamined Patent Application Publication No. 2017/0350760

### SUMMARY OF INVENTION

### Technical Problem

However, in the filter unit to which the above-described structure is applied, it is difficult to thin the filter unit in an optical axis direction (that is, the direction in which a pair of mirror sections face each other) of the Fabry-Perot interference filter, and it is difficult to perform electrical connection from the side with respect to an optical axis direction of the Fabry-Perot interference filter. Therefore, there is a problem that the filter unit is not suitable for disposition in a region (for example, a region between lenses in a lens barrel) narrow in the optical axis direction of the Fabry-Perot interference filter.

An object of the present disclosure is to provide a filter unit suitable for disposition in a region narrow in an optical axis direction of a Fabry-Perot interference filter.

### Solution to Problem

A filter unit according to one aspect of the present disclosure may be [1] “a filter unit including: a support having a light passing portion; a Fabry-Perot interference filter including a pair of mirror sections facing each other in a first direction and having a variable distance from each other, the Fabry-Perot interference filter being disposed on the support so as to overlap the light passing portion when viewed from the first direction; and a wiring substrate disposed on the support so as not to overlap the Fabry-Perot interference filter when viewed from the first direction and electrically connected to the Fabry-Perot interference filter, in which a recessed portion is formed in the support with the first direction as a depth direction, the recessed portion reaches an outer edge of the support when viewed from the first direction, and the wiring substrate is disposed in the recessed portion”.

In the filter unit according to [1], the wiring substrate does not overlap the Fabry-Perot interference filter on the support when viewed from the first direction, and is disposed in the recessed portion formed in the support with the first direction as the depth direction. As a result, for example, the filter unit can be made thinner in the first direction that is the optical axis direction (that is, the direction in which the pair of mirror sections faces each other) of the Fabry-Perot interference filter. In addition, the recessed portion in which the wiring substrate is disposed reaches the outer edge of the support when viewed from the first direction. As a result, it is possible to implement electrical connection from the side with respect to the first direction that is the optical axis direction of the Fabry-Perot interference filter. Therefore, the filter unit according to [1] is suitable for disposition in a region narrow in the optical axis direction of the Fabry-Perot interference filter.

A filter unit according to one aspect of the present disclosure may be [2] “the filter unit according to [1], in which the Fabry-Perot interference filter is positioned at a center of the support when viewed from the first direction”. According to the filter unit described in [2], even if an external force acts on the support from the side with respect to the first direction, the external force can be suppressed from reaching the Fabry-Perot interference filter. In addition, for example, the Fabry-Perot interference filter can be disposed on a center line of a tube by fitting the support inside the tube such as a lens barrel.

A filter unit according to one aspect of the present disclosure may be [3] “the filter unit according to [2], in which the outer edge of the support has a circular shape when viewed from the first direction”. According to the filter unit described in [3], even if the external force acts on the support from the side with respect to the first direction, it is possible to suppress the external force from being applied to the Fabry-Perot interference filter in a well-balanced manner. In addition, for example, when the tube has a cylindrical shape, the Fabry-Perot interference filter can be easily and accurately disposed on the center line of the tube.

A filter unit according to one aspect of the present disclosure may be [4] “the filter unit according to any one of [1] to [3], in which another recessed portion opened on an opposite side of the light passing portion with the first direction as a depth direction is formed in the support, the Fabry-Perot interference filter is disposed in the another recessed portion, and each of an outer edge of the Fabry-Perot interference filter and an inner edge of the another recessed portion has a rectangular shape when viewed from the first direction”. According to the filter unit described in [4], since the Fabry-Perot interference filter is disposed in another recessed portion formed in the support with the first direction as the depth direction, the filter unit can be made thinner in the first direction that is the optical axis direction of the Fabry-Perot interference filter. In addition, since each of the outer edge of the Fabry-Perot interference filter and the inner edge of another recessed portion has a rectangular shape when viewed from the first direction, the Fabry-Perot interference filter can be easily and accurately positioned with respect to the support. A filter unit according to one aspect of the present disclosure may

be [5] “the filter unit according to any one of [1] to [4], in which the Fabry-Perot interference filter is disposed on a first mounting surface of the support, the wiring substrate is disposed on a second mounting surface of the support, and the first mounting surface and the second mounting surface are positioned on the same plane”. According to the filter unit described in [5], the filter unit can be made thinner in the first direction that is the optical axis direction of the Fabry-Perot interference filter.

A filter unit according to one aspect of the present disclosure may be [6] “the filter unit according to any one of [1] to [5], in which another recessed portion opened on an opposite side of the light passing portion with the first direction as a depth direction is formed in the support, the Fabry-Perot interference filter is disposed in the another recessed portion, and the support includes a partition disposed between the recessed portion and the another recessed portion”. According to the filter unit described in [6], since the Fabry-Perot interference filter is disposed in another recessed portion formed in the support with the first direction as the depth direction, the filter unit can be made thinner in the first direction that is the optical axis direction of the Fabry-Perot interference filter. In addition, the Fabry-Perot interference filter and the wiring substrate can be easily and accurately positioned with respect to the support by using the partition as a reference.

A filter unit according to one aspect of the present disclosure may be [7] “the filter unit according to any one of [1] to [6], further including a light transmitting member and an adhesive member, in which another recessed portion opened on an opposite side of the light passing portion with the first direction as a depth direction is formed in the support, the Fabry-Perot interference filter is disposed in the another recessed portion, the light transmitting member covers at least an opening of the another recessed portion, and the adhesive member is disposed between the wiring substrate and the support and between the wiring substrate and the light transmitting member”. According to the filter unit described in [7], it is possible to form a package that accommodates the Fabry-Perot interference filter by the support, the wiring substrate, the light transmitting member, and the adhesive member while suppressing an increase in the thickness in the first direction that is the optical axis direction of the Fabry-Perot interference filter. As a result, the Fabry-Perot interference filter can be protected from moisture, particles, and the like.

A filter unit according to one aspect of the present disclosure may be [8] “the filter unit according to any one of [1] to [7], in which another recessed portion opened on an opposite side of the light passing portion with the first direction as a depth direction is formed in the support, the Fabry-Perot interference filter is disposed in the another recessed portion, and a distance from an inner edge of the another recessed portion to the outer edge of the support in one direction is larger than a width of the Fabry-Perot interference filter in the one direction when viewed from the first direction”. According to the filter unit described in [8], since the Fabry-Perot interference filter is disposed in another recessed portion formed in the support with the first direction as the depth direction, the filter unit can be made thinner in the first direction that is the optical axis direction of the Fabry-Perot interference filter. In addition, when viewed from the first direction, since the distance from the inner edge of another recessed portion to the outer edge of the support in one direction is larger than the width of the Fabry-Perot interference filter in the one direction, even if an external force acts on the support from the side with respect to the first direction, it is possible to suppress the external force from reaching the Fabry-Perot interference filter.

The filter unit according to one aspect of the present disclosure may be [9] “the filter unit according to any one of [1] to [8], in which another recessed portion opened on an opposite side of the light passing portion with the first direction as a depth direction is formed in the support, the Fabry-Perot interference filter is disposed in the another recessed portion, the light passing portion is an opening formed in the support, an outer edge of the Fabry-Perot interference filter has a rectangular shape when viewed from the first direction, a distance from the outer edge of the Fabry-Perot interference filter to the outer edge of the support in a direction perpendicular to one side of the outer edge of the Fabry-Perot interference filter is larger than a length of a diagonal line of the outer edge of the Fabry-Perot interference filter when viewed from the first direction, and a width of the opening is smaller than a width of the Fabry-Perot interference filter in the direction perpendicular to the one side when viewed from the first direction”. According to the filter unit described in [9], since the Fabry-Perot interference filter is disposed in another recessed portion formed in the support with the first direction as the depth direction, the filter unit can be made thinner in the first direction that is the optical axis direction of the Fabry-Perot interference filter. In addition, since the opening is very small as compared with the support when viewed from the first direction, it is possible to suppress stray light from entering the Fabry-Perot interference filter.

The filter unit according to one aspect of the present disclosure may be [10] “the filter unit according to any one of [1] to [9], in which another recessed portion opened on an opposite side of the light passing portion with the first direction as a depth direction is formed in the support, the recessed portion and the another recessed portion are arranged in a second direction perpendicular to the first direction, the Fabry-Perot interference filter is disposed in the another recessed portion, and when a width of the Fabry-Perot interference filter in a third direction perpendicular to both the first direction and the second direction is set as Wf, a width of the wiring substrate in the third direction is set as Ws, a width of the another recessed portion in the third direction is set as W1, and a width of the recessed portion in the third direction is set as W2, a relationship of “Wf≤W1<Ws≤W2” or a relationship of “Ws≤W2<Wf≤W2” is established”. According to the filter unit described in [10], since the Fabry-Perot interference filter is disposed in another recessed portion formed in the support with the first direction as the depth direction, the filter unit can be made thinner in the first direction that is the optical axis direction of the Fabry-Perot interference filter. In addition, since the width W1 of another recessed portion and the width W2 of the recessed portion are different from each other, positioning of the Fabry-Perot interference filter and the wiring substrate with respect to the support can be easily and accurately performed by using a boundary portion between the another recessed portion and the recessed portion as a reference (for example, a mechanical positioning unit or a reference coordinate). In addition, the strength of the support can be secured as compared with a case where the smaller width of the width W1 of the another recessed portion and the width W2 of the recessed portion is matched with the larger width. Furthermore, in a case where the relationship of “Wf≤W1<Ws≤W2” is satisfied, even if the external force acts on the wiring substrate from the side with respect to the first direction, the external force can be released from the boundary portion between the first recessed portion and the second recessed portion to the support, and it is possible to suppress the external force from being applied to the Fabry-Perot interference filter. On the other hand, in a case where the relationship of “Ws≤W2<Wf≤W1” is satisfied, it is possible to suppress stray light from entering the Fabry-Perot interference filter via the second recessed portion in which the wiring substrate is disposed.

The filter unit according to one aspect of the present disclosure may be [11] “the filter unit according to [10], in which a relationship of “Wf=W1” is satisfied”. According to the filter unit described in [11], the Fabry-Perot interference filter can be more easily positioned with respect to the support with higher accuracy.

The filter unit according to one aspect of the present disclosure may be [12] “the filter unit according to or [11], in which a relationship of “Ws=W2” is satisfied”. According to the filter unit described in [12], positioning of the wiring substrate with respect to the support can be performed more easily and more accurately.

A filter unit according to one aspect of the present disclosure may be [13] “the filter unit according to any one of [1] to [12], in which another recessed portion opened on an opposite side of the light passing portion with the first direction as a depth direction is formed in the support, the Fabry-Perot interference filter is disposed in the another recessed portion, and a through-hole opened to an inner surface of the another recessed portion and an outer surface of the support is formed in the support”. According to the filter unit described in [13], since the Fabry-Perot interference filter is disposed in another recessed portion formed in the support with the first direction as the depth direction, the filter unit can be made thinner in the first direction that is the optical axis direction of the Fabry-Perot interference filter. In addition, for example, at the time of manufacturing the filter unit, even if gas is generated in another recessed portion in a state where the opening of another recessed portion is covered with some member, the gas can be released from the through-hole to the outside.

### Advantageous Effects of Invention

According to the present disclosure, it is possible to provide a filter unit suitable for disposition in a region narrow in an optical axis direction of a Fabry-Perot interference filter.

### BRIEF DESCRIPTION OF DRAWINGS

FIG. 1 is a perspective view of a Fabry-Perot interference filter included in a filter unit of an embodiment.

FIG. 2 is a cross-sectional view of the Fabry-Perot interference filter taken along line II-II illustrated in FIG. 1.

FIG. 3 is a plan view of the filter unit according to the embodiment.

FIG. 4 is a cross-sectional view of the filter unit taken along line IV-IV in FIG. 3.

FIG. 5 is a plan view of a part of the filter unit according to the embodiment.

FIG. 6 is a plan view of a part of the filter unit according to the embodiment.

FIG. 7 is a bottom view of the filter unit according to the embodiment.

FIG. 8 is a cross-sectional view of a lens barrel including the filter unit according to the embodiment.

FIG. 9 is a plan view of a part of a filter unit according to a modification.

FIG. 10 is a cross-sectional view of a part of a lens barrel including the filter unit according to a modification.

FIG. 11 is a cross-sectional view of a Fabry-Perot interference filter according to a modification.

### DESCRIPTION OF EMBODIMENTS

Hereinafter, embodiments of the present disclosure will be described in detail with reference to the drawings. Note that, in the drawings, the same or corresponding parts are denoted by the same reference signs, and redundant description will be omitted.

### [Configuration of Fabry-Perot Interference Filter Included in Filter Unit]

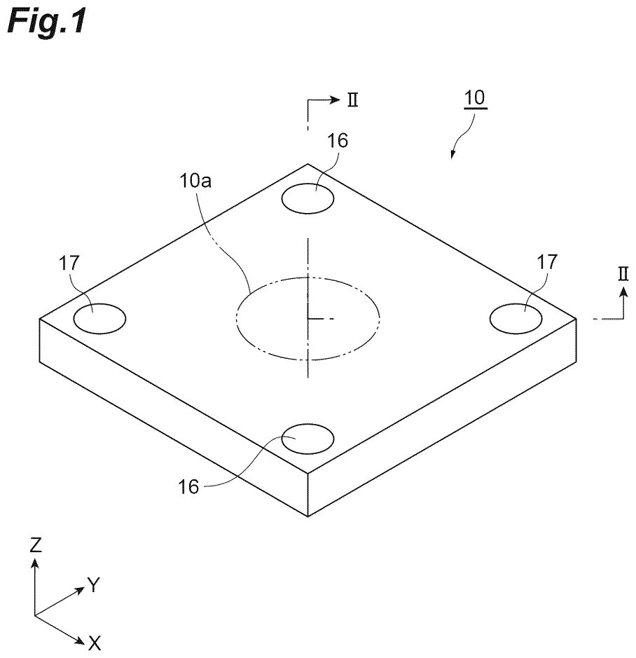

As illustrated in FIG. 1, a Fabry-Perot interference filter 10 includes a light transmission region 10a. The Fabry-Perot interference filter 10 is a rectangular plate-shaped element whose thickness direction is a Z-axis direction. The light transmission region 10a is a columnar region having a center line parallel to the Z-axis direction. When viewed from the Z-axis direction, the center of the light transmission region 10a coincides with the center of the Fabry-Perot interference filter 10.

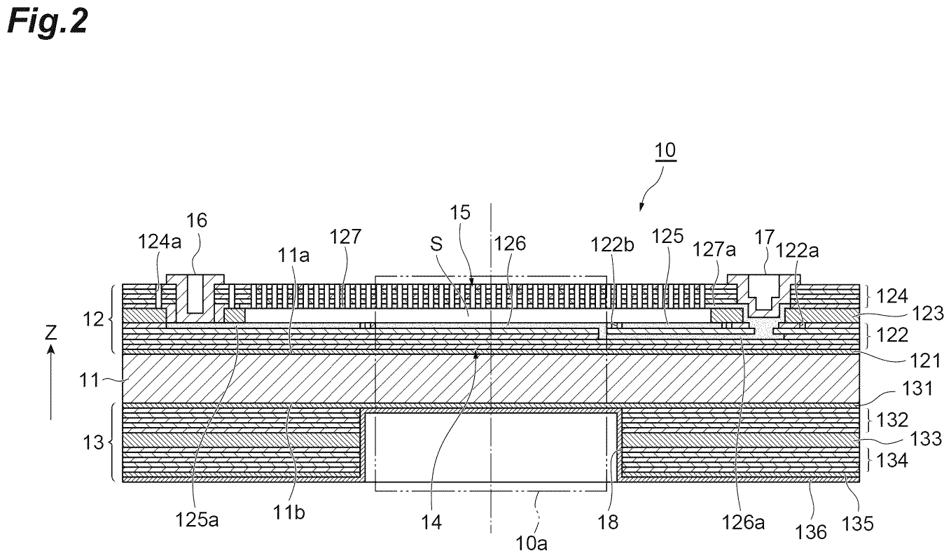

As illustrated in FIG. 2, the Fabry-Perot interference filter 10 includes a substrate 11 with the Z-axis direction as a thickness direction. The material of the substrate 11 is, for example, silicon, quartz, glass, or the like. The substrate 11 includes a pair of surfaces 11a and 11b. The pair of surfaces 11a and 11b face each other in the Z-axis direction. A first stacked structure 12 is stacked on the surface 11a of the substrate 11. The second stacked structure 13 is stacked on the surface 11b of the substrate 11.

The first stacked structure 12 includes an anti-reflective layer 121, a first stacked body 122, an intermediate layer 123, and a second stacked body 124. The anti-reflective layer 121, the first stacked body 122, the intermediate layer 123, and the second stacked body 124 are stacked on the surface 11a of the substrate 11 in this order. A gap (air gap) S is formed between the first stacked body 122 and the second stacked body 124 by the intermediate layer 123 of a frame shape. When the material of the substrate 11 is silicon, the material of each of the anti-reflective layer 121 and the intermediate layer 123 is, for example, silicon oxide or the like. A thickness of the intermediate layer 123 is, for example, an integral multiple of ½ of a design center wavelength. Note that the thickness of the intermediate layer 123 may be larger than the integral multiple of ½ of the design center wavelength, as necessary.

A part of the first stacked body 122 corresponding to the light transmission region 10a functions as the mirror section 14. The mirror section 14 is supported by the substrate 11 via the anti-reflective layer 121. As an example, the first stacked body 122 includes a plurality of polysilicon layers and a plurality of silicon nitride layers, each layer of which stacked alternately. An optical thickness of each of the layers configuring the mirror section 14 is, for example, an integral multiple of ¼ of the design center wavelength. Note that a silicon oxide layer may be used instead of the silicon nitride layer.

A part of the second stacked body 124 corresponding to the light transmission region 10a functions as the mirror section 15. The mirror section 15 is supported on the substrate 11 via the anti-reflective layer 121, the first stacked body 122, and the intermediate layer 123, and faces the mirror section 14 via a gap S. As an example, the second stacked body 124 includes a plurality of polysilicon layers and a plurality of silicon nitride layers, each layer of which stacked alternately. An optical thickness of each of the layers configuring the mirror section 15 is, for example, an integral multiple of ¼ of the design center wavelength. Note that a silicon oxide layer may be used instead of the silicon nitride layer. A plurality of through-holes are formed in a part of the second stacked body 124 corresponding to the gap S so as not to substantially affect the function of the mirror section 15. The plurality of through-holes are used when the gap S is formed by removing a portion of the intermediate layer 123 by etching.

A first electrode 125 and a second electrode 126 are formed in the mirror section 14. The first electrode 125 surrounds the light transmission region 10a when viewed from the Z-axis direction. The second electrode 126 overlaps the light transmission region 10a when viewed from the Z-axis direction. The shape of the second electrode 126 when viewed from the Z-axis direction is substantially the same as the shape of the light transmission region 10a when viewed from the Z-axis direction. Each of the first electrode 125 and the second electrode 126 is formed by doping a part of a polysilicon layer with an impurity to lower the resistance of the part.

In the mirror section 15, a third electrode 127 is formed. The third electrode 127 faces the first electrode 125 and the second electrode 126 via the gap S. The third electrode 127 is formed by doping a part of a polysilicon layer with an impurity to lower the resistance of the part. As an example, the distance between the second electrode 126 and the third electrode 127 is substantially the same as the distance between the first electrode 125 and the third electrode 127.

The first stacked structure 12 is provided with a pair of terminals 16 so as to sandwich the light transmission region 10a (refer to FIG. 1). Each terminal 16 is disposed in a through-hole formed in the second stacked body 124 and the intermediate layer 123 so as to open on the opposite side of the substrate 11 and reach the first stacked body 122. Each of the terminals 16 is electrically connected to the first electrode 125 via wiring 125a.

The first stacked structure 12 is provided with a pair of terminals 17 so as to sandwich the light transmission region 10a (refer to FIG. 1).

Each terminal 17 is disposed in a through-hole formed in the second stacked body 124 and the intermediate layer 123 so as to open on the opposite side of the substrate 11 and reach the intermediate layer 123. Each of the terminals 17 is electrically connected to the second electrode 126 via wiring 126a and is also electrically connected to the third electrode 127 via wiring 127a. Note that a direction in which the pair of terminals 17 are disposed with the light transmission region 10a interposed therebetween is a direction perpendicular to a direction in which the pair of terminals 16 are disposed with the light transmission region 10a interposed therebetween (refer to FIG. 1).

A pair of trenches 122a are formed in the first stacked body 122. Each of the trenches 122a annularly extends in such a manner as to surround a part of the wiring 126a extending from each terminal 17 along the Z-axis direction. Each of the trenches 122a electrically insulates the first electrode 125 from the wiring 126a. A trench 122b is formed in the first stacked body 122. The trench 122b annularly extends along an inner edge of the first electrode 125. The trench 122b electrically insulates the first electrode 125 from the second electrode 126. Regions inside the trenches 122a and 122b may be filled with an insulating material or a gap.

A pair of trenches 124a are formed in the second stacked body 124. Each of the trenches 124a annularly extends in such a manner as to surround each of the terminals 16. Each of the trenches 124a electrically insulates each of the terminals 16 from the third electrode 127. Regions inside the trenches 124a may be filled with an insulating material or a gap.

The second stacked structure 13 includes an anti-reflective layer 131, a third stacked body 132, an intermediate layer 133, and a fourth stacked body 134. The anti-reflective layer 131, the third stacked body 132, the intermediate layer 133, and the fourth stacked body 134 are stacked on the surface 11b of the substrate 11 in this order. The anti-reflective layer 131 and the intermediate layer 133 have a similar configuration to those of the anti-reflective layer 121 and the intermediate layer 123, respectively. The third stacked body 132 and the fourth stacked body 134 have stacked structures symmetrical to those of the first stacked body 122 and the second stacked body 124, respectively, with respect to the substrate 11. The anti-reflective layer 131, the third stacked body 132, the intermediate layer 133, and the fourth stacked body 134 have a function of suppressing warping of the substrate 11.

In the third stacked body 132, the intermediate layer 133, and the fourth stacked body 134, an opening 18 is formed in such a manner as to include the light transmission region 10a. The opening 18 overlaps the light transmission region 10a when viewed from the Z-axis direction. The shape of the opening 18 when viewed from the Z-axis direction is substantially the same as the shape of the light transmission region 10a when viewed from the Z-axis direction. That is, the center line of the opening 18 coincides with the center line of the light transmission region 10a. The opening 18 is open on the side opposite to the substrate 11 and reaches the anti-reflective layer 131.

A light shielding layer 135 is formed on a surface of the fourth stacked body 134 opposite to the substrate 11. The material of the light shielding layer 135 is, for example, aluminum or the like. A protective layer 136 is formed on a surface of the light shielding layer 135 and an inner surface of the opening 18. The material of the protective layer 136 is, for example, aluminum oxide or the like. Note that by setting a thickness of the protective layer 136 to 100 nm or less (preferably, about 30 nm), optical influence by the protective layer 136 can be made negligible.

In the Fabry-Perot interference filter 10 configured as described above, when a potential difference is generated between the first electrode 125 and the third electrode 127 by applying a voltage to the first electrode 125 and the third electrode 127 via the plurality of terminals 16 and 17, an electrostatic force corresponding to the potential difference is generated between the first electrode 125 and the third electrode 127. With the electrostatic force generated between the first electrode 125 and the third electrode 127, the mirror section 15 is attracted toward the mirror section 14, and the distance between the mirror section 14 and the mirror section 15 is adjusted. At this point, the second electrode 126 having the same potential as that of the third electrode 127 functions as a compensation electrode, and the mirror section 15 is kept flat in the light transmission region 10a.

As described above, in the Fabry-Perot interference filter 10, the pair of mirror sections 14 and 15 facing each other in the Z-axis direction functions as a pair of mirror sections whose distance from each other is variable. Here, the wavelength of light transmitted through the Fabry-Perot interference filter 10 depends on the distance between the mirror section 14 and the mirror section 15. Therefore, the wavelength of the light transmitted through the Fabry-Perot interference filter 10 can be selected by adjusting the voltage (potential difference generated between the first electrode 125 and the third electrode 127) applied to the first electrode 125 and the third electrode 127.

### [Configuration of Filter Unit]

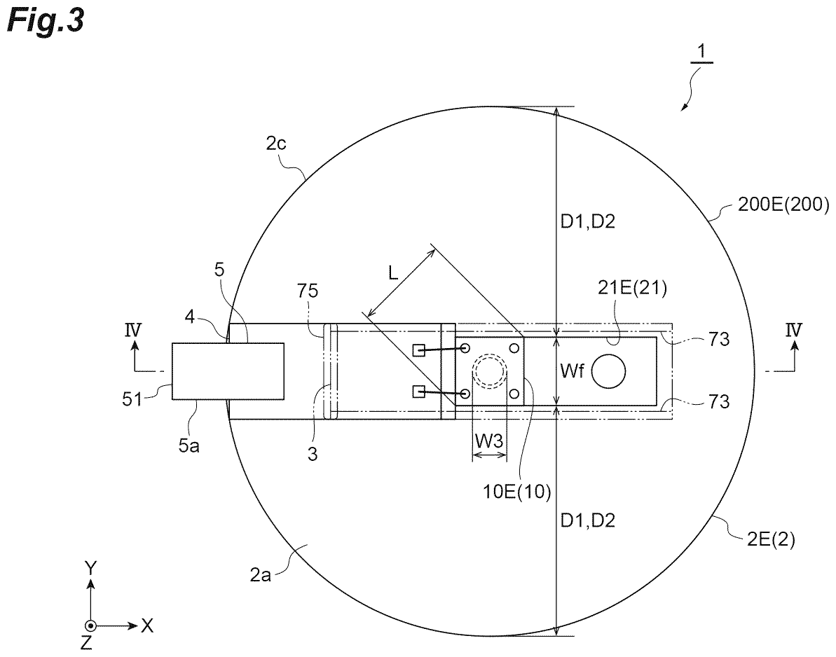

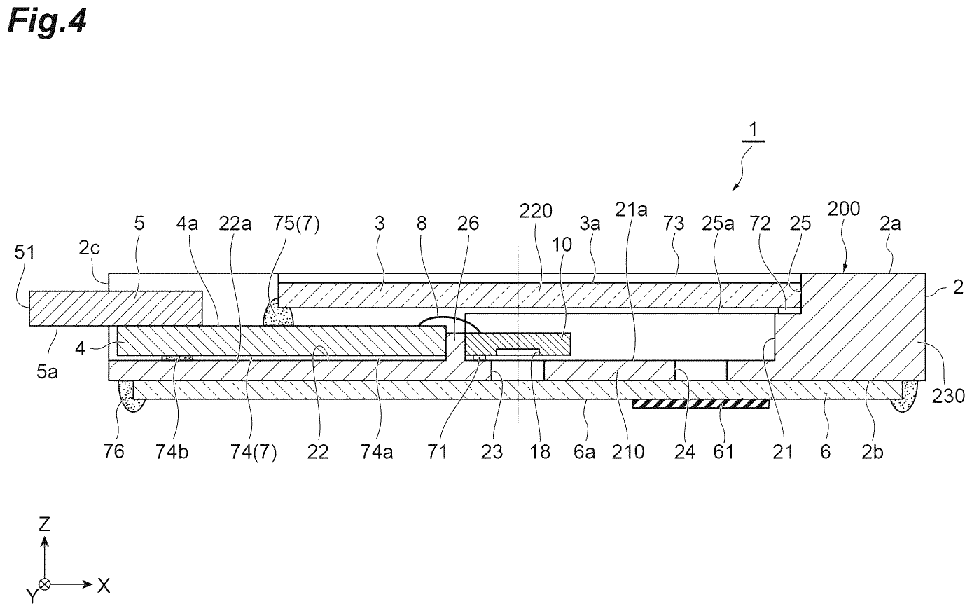

As illustrated in FIGS. 3 and 4, a filter unit 1 includes a support 2, a light transmitting member 3, a wiring substrate 4, a connector 5, a cover 6, and the Fabry-Perot interference filter 10 described above. In FIG. 3, the light transmitting member 3 and adhesive members 73 and 75 described later are indicated by two-dot chain lines.

The support 2 is a circular plate-shaped member whose thickness direction is the Z-axis direction (first direction). That is, when viewed from the Z-axis direction, an outer edge 2E of the support 2 has a circular shape. The support 2 has a pair of surfaces 2a and 2b and a side surface 2c. The pair of surfaces 2a and 2b face each other in the Z-axis direction. The side surface 2c connects the outer edge of the surface 2a and the outer edge of the surface 2b. The material of the support 2 is, for example, a metal material such as stainless steel or a resin material. The outer diameter of the support 2 is, for example, 20 mm to 50 mm. The thickness of the support 2 in the Z-axis direction is, for example, 2 mm to 5 mm.

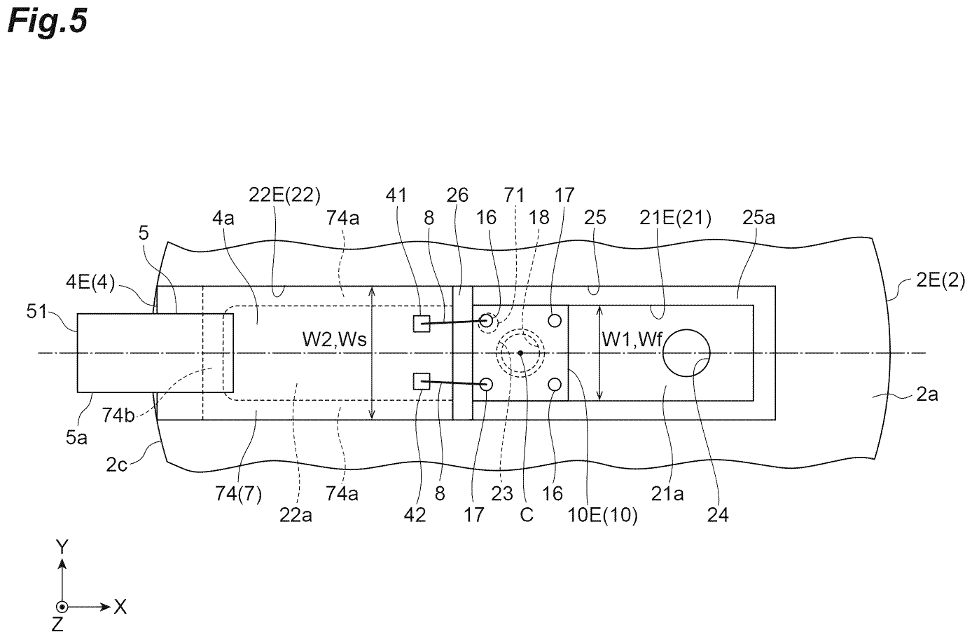

As illustrated in FIGS. 4 and 5, a first recessed portion (another recessed portion) 21 and a second recessed portion (recessed portion) 22 are formed in the support 2. Each of the first recessed portion 21 and the second recessed portion 22 opens toward the surface 2a with the Z-axis direction as the depth direction. The bottom surface (first mounting surface) 21a of the first recessed portion 21 and the bottom surface (second mounting surface) 22a of the second recessed portion 22 are positioned on the same plane perpendicular to the Z-axis direction. The thickness from bottom surfaces 21a and 22a to the surface 2b of the support 2 in the Z-axis direction is, for example, about 100 μm. The first recessed portion 21 and the second recessed portion 22 are arranged in the X-axis direction (second direction perpendicular to the first direction). In FIG. 5, illustration of the light transmitting member 3 and adhesive members 73 and 75 to be described later is omitted.

The first recessed portion 21 includes a center C of the support 2 when viewed from the Z-axis direction. The first recessed portion 21 does not reach the outer edge 2E of the support 2 when viewed from the Z-axis direction. When viewed from the Z-axis direction, the inner edge 21E of the first recessed portion 21 has a rectangular shape. In the present embodiment, when viewed from the Z-axis direction, the inner edge 21E of the first recessed portion 21 has a rectangular shape with the X-axis direction as the longitudinal direction. The width of the first recessed portion 21 in the X-axis direction is, for example, 5 mm to 20 mm. The width of the first recessed portion 21 in the Y-axis direction is, for example, 2.2 mm to 22 mm. The depth of the first recessed portion 21 in the Z-axis direction is, for example, 0.2 mm to 2 mm.

The second recessed portion 22 does not include the center C of the support 2 when viewed from the Z-axis direction. The second recessed portion 22 reaches the outer edge 2E of the support 2 when viewed from the Z-axis direction. When viewed from the Z-axis direction, the inner edge 22E of the second recessed portion 22 has a rectangular shape. In the present embodiment, when viewed from the Z-axis direction, the inner edge 22E of the second recessed portion 22 has a rectangular shape with the X-axis direction as the longitudinal direction. In the present embodiment, the second recessed portion 22 reaches the side surface 2c of the support 2 on the side opposite to the first recessed portion 21 in the X-axis direction. The second recessed portion 22 reaches the outer edge 2E of the support 2 on the short side of the second recessed portion 22 when viewed from the Z-axis direction. Since the second recessed portion 22 does not cross support 2 when viewed from the Z-axis direction, the support 2 has higher rigidity than a configuration in which the second recessed portion 22 crosses the support 2. The width of the second recessed portion 22 in the X-axis direction is, for example, 8 mm to 23 mm. The width of the second recessed portion 22 in the Y-axis direction is, for example, 3 mm to 24 mm. The depth of the second recessed portion 22 in the Z-axis direction is, for example, 0.2 mm to 2 mm.

A width W2 of the second recessed portion 22 in the Y-axis direction (third direction perpendicular to both the first direction and the second direction) is larger than a width W1 of the first recessed portion 21 in the Y-axis direction. In the present embodiment, when viewed from the Z-axis direction, the center line of the first recessed portion 21 parallel to the X-axis direction passes through the center C of the support 2. In the present embodiment, when viewed from the Z-axis direction, the center line of the second recessed portion 22 parallel to the X-axis direction coincides with the center line of the first recessed portion 21 parallel to the X-axis direction.

An opening (light passing portion) 23 and a through-hole 24 are formed in the support 2. The opening 23 and the through-hole 24 are open to the bottom surface (inner surface) 21a of the first recessed portion 21 and the surface (outer surface) 2b of the support 2, respectively. That is, the first recessed portion 21 is opened on the side opposite to the opening 23 with the Z-axis direction as the depth direction. The opening 23 and the through-hole 24 are arranged in the X-axis direction. The opening 23 defines a columnar space having a center line parallel to the Z-axis direction. When viewed from the Z-axis direction, the center of opening 23 coincides with center C of the support 2. The inner diameter of the opening 23 is, for example, 2 mm to 15 mm.

A widened portion 25 is formed on the support 2. The widened portion 25 is widened to the side opposite to the second recessed portion 22 in the X-axis direction and to both sides in the Y-axis direction with respect to the opening of the first recessed portion 21. The widened portion 25 is a recessed portion formed in the support 2 so as to open toward the surface 2a with the Z-axis direction as the depth direction and to reach the opening of the first recessed portion 21. In the present embodiment, the width of the widened portion 25 in the Y-axis direction is equal to the width W2 of the second recessed portion 22 in the Y-axis direction.

The support 2 includes a partition 26. The partition 26 is disposed between the first recessed portion 21 and the second recessed portion 22. The partition 26 is formed integrally with the other part of the support 2 as a part of the support 2. In the present embodiment, the partition 26 is a wall portion extending in the Y-axis direction between the bottom surface 21a of the first recessed portion 21 and the bottom surface 22a of the second recessed portion 22. In the present embodiment, with the plane where the bottom surface 21a and the bottom surface 22a are positioned as a reference, the height of the partition 26 in the Z-axis direction is lower than the height of the surface 2a of the support 2 in the Z-axis direction and lower than the height of a bottom surface 25a of the widened portion 25 in the Z-axis direction. The width of the partition 26 in the X-axis direction is, for example, 0.5 mm to 5 mm. The height of the partition 26 in the Z-axis direction is, for example, 0.1 mm to 2 mm.

The Fabry-Perot interference filter 10 is disposed on the support 2 with the Z-axis direction as the thickness direction so as to overlap the opening 23 when viewed from the Z-axis direction. More specifically, the Fabry-Perot interference filter 10 is disposed in the first recessed portion 21 with the Z-axis direction as the thickness direction so as to overlap the opening 23 when viewed from the Z-axis direction. The Fabry-Perot interference filter 10 is in contact with the partition 26 in the first recessed portion 21. In the present embodiment, with the bottom surface 21a of the first recessed portion 21 as a reference, the height of the Fabry-Perot interference filter 10 in the Z-axis direction is lower than the height of the surface 2a of the support 2 in the Z-axis direction and lower than the height of the bottom surface 25a of the widened portion 25 in the Z-axis direction. In the present embodiment, with the bottom surface 21a of the first recessed portion 21 as a reference, the height of the partition 26 in the Z-axis direction is equal to or less than the height of the Fabry-Perot interference filter 10 in the Z-axis direction. The width of the Fabry-Perot interference filter 10 in the X-axis direction is, for example, 2 mm to 20 mm. The width of the Fabry-Perot interference filter 10 in the Y-axis direction is, for example, 2 mm to 20 mm. The thickness of the Fabry-Perot interference filter 10 in the Z-axis direction is, for example, 300 μm to 650 μm.

As described above, the Fabry-Perot interference filter 10 is a rectangular plate-shaped element whose thickness direction is a Z-axis direction. Therefore, the outer edge 10E of the Fabry-Perot interference filter 10 has a rectangular shape when viewed from the Z-axis direction. The Fabry-Perot interference filter 10 is disposed on the bottom surface 21a of the first recessed portion 21 such that each side of the outer edge 10E is parallel to the X-axis direction or the Y-axis direction when viewed from the Z-axis direction and the opening 18 faces the opening 23. The center line of the opening 18 coincides with the center line of the opening 23. That is, when viewed from the Z-axis direction, the Fabry-Perot interference filter 10 is positioned at the center C of the support 2. When viewed from the Z-axis direction, the opening 18 is positioned inside the opening 23.

The Fabry-Perot interference filter 10 is fixed to the bottom surface 21a by an adhesive member 71. The adhesive member 71 is disposed in a dot shape between the bottom surface 21a and one corner portion of the Fabry-Perot interference filter 10. As a result, it is possible to suppress the stress caused by the deformation of the support 2 and/or the adhesive member 71 due to the temperature change from being applied to the Fabry-Perot interference filter 10. The material of the adhesive member 71 is, for example, a polyimide-based resin, a silicone resin, an epoxy-based resin, an acrylic resin, or a hybrid resin thereof.

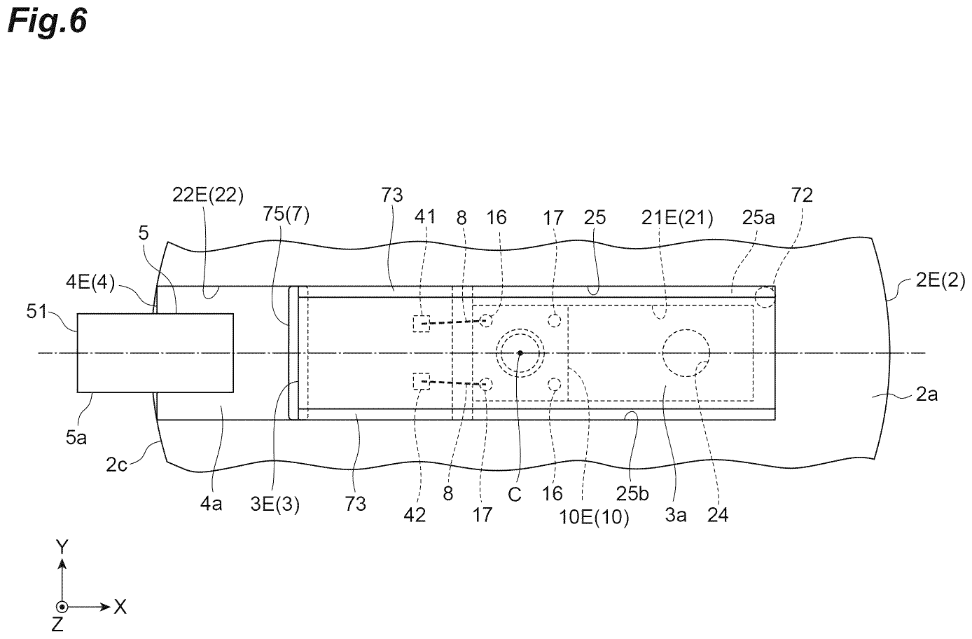

As illustrated in FIGS. 4 and 6, the light transmitting member 3 is disposed on the support 2 with the Z-axis direction as the thickness direction so as to cover the opening of the first recessed portion 21. More specifically, the light transmitting member 3 is disposed in the widened portion 25 with the Z-axis direction as the thickness direction so as to cover the opening of the first recessed portion 21. In the present embodiment, the light transmitting member 3 covers a part of the opening of the second recessed portion 22 together with the opening of the first recessed portion 21. In the present embodiment, with the bottom surface 25a of the widened portion 25 as a reference, the height of the light transmitting member 3 in the Z-axis direction is lower than the height of the surface 2a of the support 2 in the Z-axis direction.

The light transmitting member 3 is a rectangular plate-shaped member whose thickness direction is the Z-axis direction and whose longitudinal direction is the X-axis direction. Therefore, when viewed from the Z-axis direction, the outer edge 3E of the light transmitting member 3 has a rectangular shape with the X-axis direction as the longitudinal direction. The light transmitting member 3 is disposed on the bottom surface 25a of the widened portion 25 such that each side of the outer edge 3E is parallel to the X-axis direction or the Y-axis direction when viewed from the Z-axis direction. As an example, the light transmitting member 3 is a band pass filter that transmits light in a predetermined wavelength range.

The light transmitting member 3 is fixed to the bottom surface 25a and the side surface 25b of the widened portion 25 by the adhesive members 72 and 73. The adhesive members 72 is disposed in a dot shape between the bottom surface 25a and one corner portion of the light transmitting member 3. The adhesive members 73 is disposed along the corner portion formed by the side surface 25b and the surface 3a of the light transmitting member 3. The surface 3a is a surface of the light transmitting member 3 opposite to the first recessed portion 21. A part of the adhesive members 73 also enters between the side surface 25b of the widened portion 25 and the side surface of the light transmitting member 3. The material of the adhesive members 72 and 73 is, for example, a polyimide-based resin, a silicone resin, an epoxy-based resin, an acrylic resin, or a hybrid resin thereof.

As illustrated in FIGS. 4 and 5, the wiring substrate 4 is disposed on the support 2 with the Z-axis direction as the thickness direction so as not to overlap the Fabry-Perot interference filter 10 when viewed from the Z-axis direction. More specifically, the wiring substrate 4 is disposed in the second recessed portion 22 with the Z-axis direction as the thickness direction so as not to overlap the Fabry-Perot interference filter 10 when viewed from the Z-axis direction. The wiring substrate 4 is in contact with the partition 26 in the second recessed portion 22. In the present embodiment, with the bottom surface 22a of the second recessed portion 22 as a reference, the height of the wiring substrate 4 in the Z-axis direction is lower than the height of the surface 2a of the support 2 in the Z-axis direction and lower than the height of the bottom surface 25a of the widened portion 25 in the Z-axis direction. In the present embodiment, with the bottom surface 22a of the second recessed portion 22 as a reference, the height of the partition 26 in the Z-axis direction is equal to or less than the height of the wiring substrate 4 in the Z-axis direction.

The wiring substrate 4 is a rectangular plate-shaped substrate having a thickness direction in the Z-axis direction and a longitudinal direction in the X-axis direction. Therefore, when viewed from the Z-axis direction, the outer edge 4E of the wiring substrate 4 has a rectangular shape with the X-axis direction as the longitudinal direction. The wiring substrate 4 is disposed on the bottom surface 22a of the second recessed portion 22 such that each side of the outer edge 4E is parallel to the X-axis direction or the Y-axis direction when viewed from the Z-axis direction.

The wiring substrate 4 is fixed to the bottom surface 22a of the second recessed portion 22 by an adhesive member 74. The adhesive member 74 includes a pair of a first part 74a and a second part 74b. The pair of first parts 74a face each other between the bottom surface 22a and the wiring substrate 4, and each extends in the X-axis direction. A part of each first part 74a also enters between the side surface of the second recessed portion 22 and the side surface of the wiring substrate 4. The second part 74b faces the partition 26 between the bottom surface 22a and the wiring substrate 4, and extends in the Y-axis direction. The material of the adhesive member 74 is, for example, a polyimide-based resin, a silicone resin, an epoxy-based resin, an acrylic resin, or a hybrid resin thereof.

The wiring substrate 4 is electrically connected to the Fabry-Perot interference filter 10. More specifically, the terminal 41 of the wiring substrate 4 is electrically connected to the terminal 16 close to the partition 26 among the pair of terminals 16 of the Fabry-Perot interference filter 10 by a wire 8, and the terminal 42 of the wiring substrate 4 is electrically connected to the terminal 17 close to the partition 26 among the pair of terminals 17 of the Fabry-Perot interference filter 10 by the wire 8. The pair of terminals 41 and 42 are disposed in a region along the partition 26 on the surface 4a of the wiring substrate 4 on the light transmitting member 3 side. Each wire 8 passes through a gap between the partition 26 and the light transmitting member 3. When viewed from the X-axis direction, each wire 8 is accommodated in the first recessed portion 21 and the second recessed portion 22. The width of the partition 26 in the X-axis direction is smaller than the width of the Fabry-Perot interference filter 10 in the X-axis direction. As a result, the distance between the Fabry-Perot interference filter 10 and the wiring substrate 4 can be shortened.

The connector 5 is mounted on the surface 4a of the wiring substrate 4 and is electrically connected to the wiring substrate 4. A part 5a of the connector 5 is positioned outside the side surface 2c of the support 2 via a region of the second recessed portion 22 reaching to the side surface 2c of the support 2. The part 5a of the connector 5 is provided with a connection port 51 that opens to the side opposite to the center C of the support 2. The connector 5 is accommodated in the second recessed portion 22 in the Z-axis direction. In the filter unit 1, a voltage is applied from an external wiring connected to the connector 5 to the pair of terminals 16 and 17 via the wiring substrate 4 and the pair of wires 8.

As illustrated in FIGS. 4 and 6, an adhesive member 75 is disposed between the wiring substrate 4 and the light transmitting member 3. The adhesive member 75 extends along a portion of the outer edge 3E of the light transmitting member 3 overlapping the wiring substrate 4 when viewed from the Z-axis direction. The adhesive member 75 seals a gap between the wiring substrate 4 and the light transmitting member 3 outside the pair of terminals 41 and 42 (on the side opposite to the center C of the support 2). The material of the adhesive member 75 is, for example, a polyimide-based resin, a silicone resin, an epoxy-based resin, an acrylic resin, or a hybrid resin thereof. In the present embodiment, the adhesive members 74 and 75 constitute “an adhesive member 7 disposed between the wiring substrate 4 and the support 2 and between the wiring substrate 4 and the light transmitting member 3”.

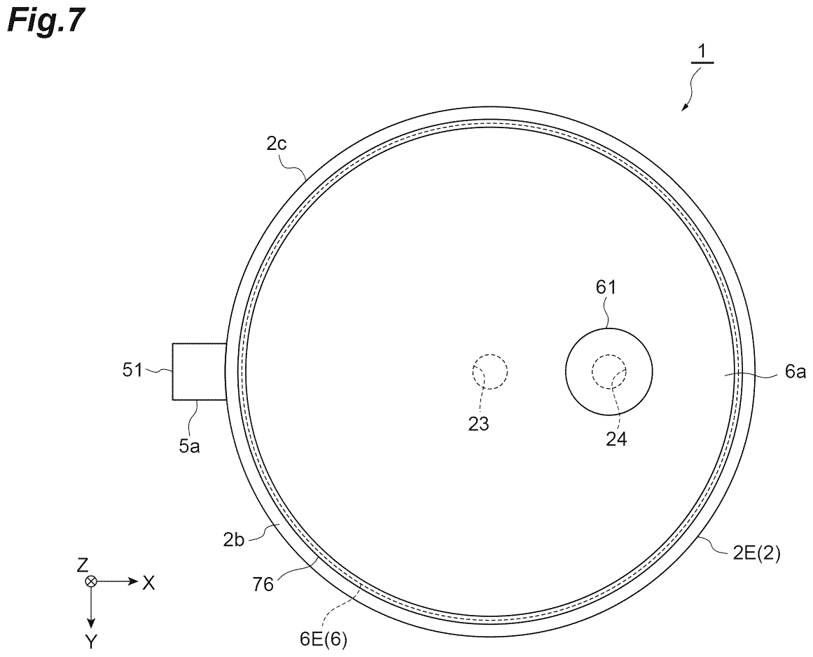

As illustrated in FIGS. 4 and 7, the cover 6 is disposed on the surface 2b of the support 2 so as to cover the opening 23 and the through-hole 24. The cover 6 is a plate-like member having optical transparency, and is disposed on the surface 2b of the support 2 with the Z-axis direction as a thickness direction. As an example, the cover 6 has a circular plate shape, and the outer edge 6E of the cover 6 is positioned inside the outer edge 2E of the support 2 when viewed from the Z-axis direction. The cover 6 is fixed to the surface 2b by an adhesive member 76 disposed along the outer edge 6E of the cover 6. The material of the adhesive member 76 is, for example, a polyimide-based resin, a silicone resin, an epoxy-based resin, an acrylic resin, or a hybrid resin thereof. A light shielding film 61 is provided on a surface 6a of the cover 6 opposite to the support 2. The light shielding film 61 overlaps the through-hole 24 when viewed from the Z-axis direction. The light shielding film 61 has a size sufficient to prevent light from entering the through-hole 24 via the cover 6. The light shielding film 61 is, for example, a chromium plating film or the like.

As illustrated in FIG. 4, in the filter unit 1, the support 2 and the light transmitting member 3 constitute a housing 200 including a first wall portion 210, a second wall portion 220, and a surrounding portion 230. More specifically, a part of the support 2 constitutes the first wall portion 210 230, and a part of the light transmitting member 3 constitutes the second wall portion 220. Another part of the support 2 and another part of the light transmitting member 3 constitute the surrounding portion 230. The first wall portion 210 is a wall portion having the opening 23, and specifically, is a portion (that is, the bottom wall portion of the first recessed portion 21) of the support 2 overlapping a region in the first recessed portion 21 when viewed from the Z-axis direction. The second wall portion 220 is a wall portion facing the first wall portion 210 in the Z-axis direction, and specifically, is a portion of the light transmitting member 3 overlapping a region in the first recessed portion 21 when viewed from the Z-axis direction. The surrounding portion 230 is a part surrounding the region between the first wall portion 210 and the second wall portion 220, and specifically, is a part surrounding the region in the first recessed portion 21 when viewed from the Z-axis direction in the support 2 and the light transmitting member 3.

Therefore, in the filter unit 1, the following can be said. The first recessed portion 21 is defined by the first wall portion 210 and the surrounding portion 230. A region in the first recessed portion 21 corresponds to a region in the housing 200. The second recessed portion 22 is formed in the surrounding portion 230 so as to open toward the second wall portion 220 with the Z-axis direction as the depth direction. When viewed from the Z-axis direction, an outer edge 200E of the housing 200 coincides with the outer edge 2E of the support 2 (refer to FIG. 3). The wiring substrate 4 is attached to the housing 200 so as not to overlap the Fabry-Perot interference filter 10 when viewed from the Z-axis direction. The wiring substrate 4 is attached to the housing 200 such that the entire wiring substrate 4 is embedded in the surrounding portion 230. Note that “the entire wiring substrate 4 is embedded in the surrounding portion 230” means that the entire wiring substrate 4 overlaps the surrounding portion 230 when viewed from any of the X-axis direction, the Y-axis direction, and the Z-axis direction. At least a part of the wiring substrate 4 is exposed to the outside of the housing 200. In the present embodiment, at least a part of the wiring substrate 4 is exposed to the outside of the housing 200 through a region of the opening of the second recessed portion 22 that is not covered with the light transmitting member 3 and a region of the second recessed portion 22 that reaches the side surface 2c of the support 2.

As illustrated in FIG. 5, a width Wf of the Fabry-Perot interference filter in the Y-axis direction is equal to or smaller than the width W1 of the first recessed portion in the Y-axis direction. A width Ws of the wiring substrate in the Y-axis direction is larger than the width W1 of the first recessed portion in the Y-axis direction and is equal to or smaller than the width W2 of the second recessed portion in the Y-axis direction. Therefore, in the filter unit 1, the relationship of “Wf≤W1<Ws≤W2” is established. In the present embodiment, the relationship of “Wf=W1” and the relationship of “Ws=W2” are established. In the filter unit 1, the relationship of “W1<2Wf” is preferably established. In the filter unit 1, the relationship of “W2<2Ws” is preferably established.

Note that “Wf=W1” means that Wf and W1 are substantially equal, and “Ws=W2” means that Ws and W2 are substantially equal. As an example, “Wf=W1” means that W1 is a value of “Wf” or more and “1.1 Wf” or less, and “Ws=W2” means that W2 is a value of “Ws” or more and “1.1 Ws” or less.

As illustrated in FIG. 3, when viewed from the Z-axis direction, the “distance D1 from the inner edge 21E of the first recessed portion 21 to the outer edge 2E of the support 2” in the Y-axis direction (one direction) is larger than the width Wf of the Fabry-Perot interference filter 10 in the Y-axis direction. The thickness of the “portion from the inner edge 21E of the first recessed portion 21 to the outer edge 2E of the support 2” in the Y-axis direction is larger than the thickness of the Fabry-Perot interference filter 10. When viewed from the Z-axis direction, the “distance D2 from the outer edge 10E of the Fabry-Perot interference filter 10 to the outer edge 2E of the support 2” in the Y-axis direction (direction perpendicular to one side of the outer edge 10E of the Fabry-Perot interference filter 10) is larger than the length L of the diagonal line of the outer edge 10E of the Fabry-Perot interference filter 10. The “distance D2 from the outer edge 10E of the Fabry-Perot interference filter 10 to the outer edge 2E of the support 2” in the Y-axis direction may be about 2 to 3 times the length L of the diagonal line of the outer edge 10E of the Fabry-Perot interference filter 10. When viewed from the Z-axis direction, the width W3 of the opening 23 is smaller than the width Wf of the Fabry-Perot interference filter 10 in the Y-axis direction. The “distance D2 from the outer edge 10E of the Fabry-Perot interference filter 10 to the outer edge 2E of the support 2” is about 2 to 3 times the length L of the diagonal line of the outer edge 10E of the Fabry-Perot interference filter 10, and the wide “distance D2 from the outer edge 10E of the Fabry-Perot interference filter 10 to the outer edge 2E of the support 2” surrounds the opening 23. The support 2 integrally formed without combining the plurality of parts includes a thick portion surrounding the first recessed portion 21 and the second recessed portion 22. The thick portion is a portion of the support 2 whose thickness in the Z-axis direction is larger than the depth of the first recessed portion 21 in the Z-axis direction. The area of the thick portion when viewed from the Z-axis direction is 50% or more of the area of the support 2 when viewed from the Z-axis direction.

The “distance D1 from the inner edge 21E of the first recessed portion 21 to the outer edge 2E of the support 2” in the predetermined direction corresponds to the “distance from the inner edge of the surrounding portion 230 to the outer edge of the surrounding portion 230” in the predetermined direction. In addition, “the distance D2 from the outer edge 10E of the Fabry-Perot interference filter 10 to the outer edge 2E of the support 2” in the predetermined direction corresponds to “the distance from the outer edge 10E of the Fabry-Perot interference filter 10 to the outer edge of the surrounding portion 230” in the predetermined direction.

### [Method for Manufacturing Filter Unit]

A method for manufacturing the above-described filter unit 1 will be described with reference to FIG. 4. First, the support 2 is prepared, and the uncured adhesive member 71 is disposed on the bottom surface 21a of the first recessed portion 21, and the uncured adhesive member 74 is disposed on the bottom surface 22a of the second recessed portion 22. Subsequently, the Fabry-Perot interference filter 10 is disposed on the bottom surface 21a of the first recessed portion 21, and the wiring substrate 4 is disposed on the bottom surface 22a of the second recessed portion 22. The connector 5 is mounted on the surface 4a of the wiring substrate 4 in advance. Subsequently, the adhesive members 71 and 74 are cured. At this time, since the Fabry-Perot interference filter 10 is fitted into the first recessed portion 21 while being in contact with the partition 26, the Fabry-Perot interference filter is accurately positioned with respect to the opening 23. In addition, since the wiring substrate 4 is fitted in the second recessed portion 22 while being in contact with the partition 26, the wiring substrate 4 is accurately positioned with respect to the Fabry-Perot interference filter 10. Subsequently, the terminal 41 of the wiring substrate 4 is electrically connected to the terminal 16 of the Fabry-Perot interference filter 10 by the wire 8, and the terminal 42 of the wiring substrate 4 is electrically connected to the terminal 17 of the Fabry-Perot interference filter 10 by the wire 8. It is important for reliably performing wire bonding between the Fabry-Perot interference filter 10 and the wiring substrate 4 that the wiring substrate 4 is accurately positioned with respect to the Fabry-Perot interference filter 10. Among the pair of terminals 16, the terminal 16 to which the wire 8 is connected is positioned closer to the partition 26 (wiring substrate 4) than the center of the Fabry-Perot interference filter 10. Similarly, among the pair of terminals 17, the terminal 17 to which the wire 8 is connected is positioned closer to the partition 26 (wiring substrate 4) than the center of the Fabry-Perot interference filter 10. Thus, the length of each wire 8 can be shortened.

Subsequently, the uncured adhesive member 72 is disposed on the bottom surface 25a of the widened portion 25. Subsequently, the light transmitting member 3 is disposed on the bottom surface 25a of the widened portion 25. Subsequently, the adhesive member 72 is cured. Subsequently, the uncured adhesive member 73 is disposed along the corner portion formed by the side surface 25b of the widened portion 25 and the surface 3a of the light transmitting member 3, and the uncured adhesive member 75 is disposed between the wiring substrate 4 and the light transmitting member 3. Subsequently, the adhesive members 73 and 75 are cured. At this time, the gas generated from the adhesive members 73 and 75 is released from the inside of the first recessed portion 21 to the outside through the through-hole 24. Subsequently, the cover 6 is disposed on the surface 2b of the support 2. Subsequently, the uncured adhesive member 76 is disposed along the outer edge 6E of the cover 6. Subsequently, the adhesive member 76 is cured. The light shielding film 61 is provided in advance on the surface 6a of the cover 6. As described above, the filter unit 1 is obtained.

### [Structure of Lens Barrel Including Filter Unit]

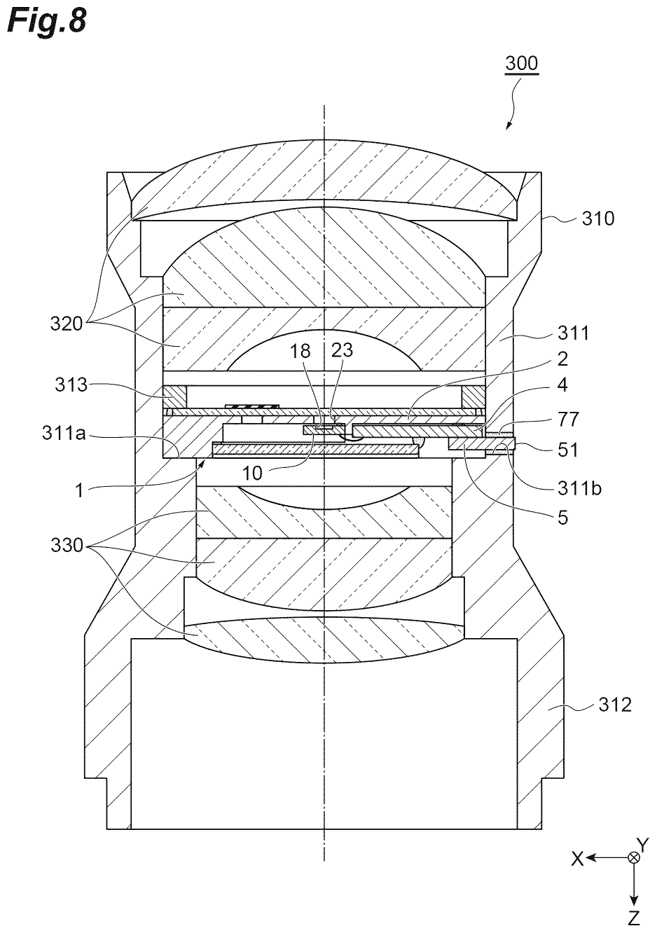

As illustrated in FIG. 8, a lens barrel 300 includes a tube 310, a condensing optical system 320 including a plurality of lenses, an imaging optical system 330 including a plurality of lenses, and the above-described filter unit 1. The lens barrel 300 is used as an interchangeable lens of a hyperspectral camera. The hyperspectral camera is a camera that can disperse light into several tens of bands to several hundreds of bands to acquire an image for each band.

The tube 310 includes a main body portion 311 and a proximal end portion 312. The main body portion 311 holds the condensing optical system 320, the imaging optical system 330, and the filter unit 1. The proximal end portion 312 is configured to be detachable from the camera body of the hyperspectral camera.

The condensing optical system 320 is disposed in a region on the side opposite to the proximal end portion 312 in the region on the inner side of the main body portion 311. The imaging optical system 330 is disposed in a region on the proximal end portion 312 side in the region inside the main body portion 311. The filter unit 1 is disposed in a region between the condensing optical system 320 and the imaging optical system 330 in a region inside the main body portion 311. The optical axis of the condensing optical system 320, the optical axis of the imaging optical system 330, and the optical axis of the filter unit 1 (that is, center lines of openings 18 and 23) coincide with the center line of the tube 310.

The condensing optical system 320 and the imaging optical system 330 constitute a non-telecentric optical system. The condensing optical system 320 is an optical system that condenses the on-axis incident light and the off-axis incident light. The filter unit 1 is disposed at a position where the on-axis incident light and the off-axis incident light intersect in the condensing optical system 320. The filter unit 1 functions as a diaphragm at the position. The imaging optical system 330 forms an image of the light having passed through the filter unit 1 on an image sensor of a hyperspectral camera. Note that the condensing optical system 320 and the imaging optical system 330 may constitute a telecentric optical system.

The filter unit 1 is fixed inside the main body portion 311 by being sandwiched between a flange surface 311a provided on the main body portion 311 and a fixing ring 313. The flange surface 311a is an inward flange surface provided on the main body portion 311 so as to face the condensing optical system 320 side. The filter unit 1 is fixed to the inside of the main body portion 311 in a state where the opening 23 is positioned on the condensing optical system 320 side with respect to the Fabry-Perot interference filter 10. As an example, the opening 23 of the filter unit 1 is positioned at a position where the on-axis incident light and the off-axis incident light of the condensing optical system 320 intersect.

The connector 5 is disposed in an opening 311b formed in the main body portion 311. The connection port 51 of the connector 5 is exposed to the outside of the tube 310 through the opening 311b. An adhesive member 77 is disposed between the side surface of the connector 5 and the inner surface of the opening 311b. Thus, a gap between the side surface of the connector 5 and the inner surface of the opening 311b is sealed.

### [Operations and Effects]

In the filter unit 1, the wiring substrate 4 does not overlap the Fabry-Perot interference filter 10 on the support 2 when viewed from the Z-axis direction, and is disposed in the second recessed portion 22 formed in the support 2 with the Z-axis direction as the depth direction. As a result, for example, the filter unit 1 can be made thinner in the Z-axis direction that is the optical axis direction (that is, the direction in which the pair of mirror sections 14 and 15 face each other) of the Fabry-Perot interference filter 10. In addition, the second recessed portion 22 in which the wiring substrate 4 is disposed reaches the outer edge 2E of the support 2 when viewed from the Z-axis direction. As a result, it is possible to implement electrical connection from the side with respect to the Z-axis direction that is the optical axis direction of the Fabry-Perot interference filter 10. Therefore, the filter unit 1 is suitable for disposition in a region narrow in the optical axis direction of the Fabry-Perot interference filter 10.

In the filter unit 1, since the configuration in which the wiring substrate 4 is disposed in the second recessed portion 22 is adopted, the position of the wiring substrate 4 in the Z-axis direction can be adjusted with respect to the Fabry-Perot interference filter 10. As a result, it is possible to facilitate wire bonding between the Fabry-Perot interference filter 10 and the wiring substrate 4.

In the filter unit 1, when viewed from the Z-axis direction, the Fabry-Perot interference filter 10 is positioned at the center C of the support 2. As a result, even if an external force acts on the support 2 from the side with respect to the Z-axis direction, the external force can be suppressed from reaching the Fabry-Perot interference filter 10. In addition, for example, the Fabry-Perot interference filter 10 can be disposed on a center line of a tube 310 by fitting the support 2 inside the tube 310 such as a lens barrel 300.

In the filter unit 1, the outer edge 2E of the support 2 has a circular shape when viewed from the Z-axis direction. As a result, even if an external force acts on the support 2 from the side with respect to the Z-axis direction, the external force can be suppressed from reaching the Fabry-Perot interference filter 10 in a well-balanced manner. In addition, for example, when the tube 310 has a cylindrical shape, the Fabry-Perot interference filter 10 can be easily and accurately disposed on the center line of the tube 310.

In the filter unit 1, since the support 2 is a circular plate-shaped member, it is possible to prevent the filter unit 1 from falling down in the tube 310 when the filter unit 1 is installed in the tube 310.

In the filter unit 1, the Fabry-Perot interference filter 10 is disposed in the first recessed portion 21, and each of the outer edge 10E of the Fabry-Perot interference filter 10 and the inner edge 21E of the first recessed portion 21 has a rectangular shape when viewed from the Z-axis direction. As a result, the filter unit 1 can be further thinned in the Z-axis direction that is the optical axis direction of the Fabry-Perot interference filter 10. In addition, since each of the outer edge 10E of the Fabry-Perot interference filter 10 and the inner edge 21E of the first recessed portion 21 has a rectangular shape when viewed from the Z-axis direction, the Fabry-Perot interference filter 10 can be easily and accurately positioned with respect to the support 2.

In the filter unit 1, the Fabry-Perot interference filter 10 and the wiring substrate 4 are disposed on the same plane (plane on which bottom surfaces 21a and 22a are positioned). As a result, the filter unit 1 can be further thinned in the Z-axis direction that is the optical axis direction of the Fabry-Perot interference filter 10.

In the filter unit 1, the support 2 includes a partition 26 disposed between the second recessed portion 22 and the first recessed portion 21. Thus, the Fabry-Perot interference filter 10 and the wiring substrate 4 can be easily and accurately positioned with respect to the support 2 by using the partition 26 as a reference.

In the filter unit 1, the light transmitting member 3 covers the opening of the first recessed portion 21, and the adhesive member 7 (adhesive members 74 and 75) is disposed between the wiring substrate 4 and the support 2 and between the wiring substrate 4 and the light transmitting member 3. As a result, it is possible to form a package that accommodates the Fabry-Perot interference filter 10 by the support 2, the wiring substrate 4, the light transmitting member 3, and the adhesive member 7 while suppressing an increase in the thickness in the Z-axis direction that is the optical axis direction of the Fabry-Perot interference filter 10. As a result, the Fabry-Perot interference filter 10 can be protected from moisture, particles, and the like.

In the filter unit 1, when viewed from the Z-axis direction, the “distance D1 from the inner edge 21E of the first recessed portion 21 to the outer edge 2E of the support 2” in the Y-axis direction is larger than the width Wf of the Fabry-Perot interference filter 10 in the Y-axis direction. As a result, even if an external force acts on the support 2 from the side with respect to the Z-axis direction, the external force can be suppressed from reaching the Fabry-Perot interference filter 10.

In the filter unit 1, “the distance D2 from the outer edge 10E of the Fabry-Perot interference filter 10 to the outer edge 2E of the support 2” in the Y-axis direction is larger than the length L of the diagonal line of the outer edge 10E of the Fabry-Perot interference filter 10, and the width W3 of the opening 23 is smaller than the width Wf of the Fabry-Perot interference filter 10 in the Y-axis direction when viewed from the Z-axis direction. As a result, since the opening 23 is very small as compared with the support 2 when viewed from the Z-axis direction, it is possible to suppress stray light from entering the Fabry-Perot interference filter 10.

In the lens barrel 300 described above, the filter unit 1 functions as a diaphragm between the condensing optical system 320 and the imaging optical system 330. As a result, the depth of field can be increased in the hyperspectral camera to which the lens barrel 300 is attached.

In the filter unit 1, a relationship of “Wf≤W1<Ws≤W2” is established for the width Wf of the Fabry-Perot interference filter 10 in the Y-axis direction, the width Ws of the wiring substrate 4 in the Y-axis direction, the width W1 of the first recessed portion 21 in the Y-axis direction, and the width W2 of the second recessed portion 22 in the Y-axis direction. As a result, since the width W1 of the first recessed portion 21 and the width W2 of the second recessed portion 22 are different from each other, positioning of the Fabry-Perot interference filter 10 and the wiring substrate 4 with respect to the support 2 can be easily and accurately performed by using a boundary portion between the first recessed portion 21 and the second recessed portion 22 as a reference (for example, a mechanical positioning unit or a reference coordinate). In addition, the strength of the support 2 can be secured as compared with a case where the width W1 of the first recessed portion 21 is matched with the width W2 of the second recessed portion 22. Furthermore, even if the external force acts on the wiring substrate 4 from the side with respect to the Z-axis direction, the external force can be released from the boundary portion between the first recessed portion 21 and the second recessed portion 22 to the support 2, and it is possible to suppress the external force from being applied to the Fabry-Perot interference filter 10.

In the filter unit 1, the width Wf of the Fabry-Perot interference filter 10 in the Y-axis direction and the width W1 of the first recessed portion 21 in the Y-axis direction satisfy the relationship of “Wf=W1”. As a result, the Fabry-Perot interference filter 10 can be more easily and more accurately positioned with respect to the support 2.

In the filter unit 1, a relationship of “Ws=W2” is established for the width Ws of the wiring substrate 4 in the Y-axis direction and the width W2 of the second recessed portion 22 in the Y-axis direction. This makes it possible to more easily and more accurately position the wiring substrate 4 with respect to the support 2.

In the filter unit 1, the support 2 is formed with the through-hole 24 opened to the bottom surface 21a of the first recessed portion 21 and the surface 2b of the support 2. As a result, even if gas is generated in the first recessed portion 21 in a state where the opening of the first recessed portion 21 is covered with the light transmitting member 3 at the time of manufacturing the filter unit 1, the gas can be released from the through-hole 24 to the outside.

### [Modifications]

The present disclosure is not limited to the above embodiment. For example, in a case where a relationship of “Wf≤W1<Ws≤W2” is established for the width Wf of the Fabry-Perot interference filter 10 in the Y-axis direction, the width Ws of the wiring substrate 4 in the Y-axis direction, the width W1 of the first recessed portion 21 in the Y-axis direction, and the width W2 of the second recessed portion 22 in the Y-axis direction (a case illustrated in FIG. 5), the relationship of “Wf<W1” may be established. Similarly, when the relationship of “Wf≤W1<Ws≤W2” is established (the case illustrated in FIG. 5), the relationship of “Ws<W2” may be established.

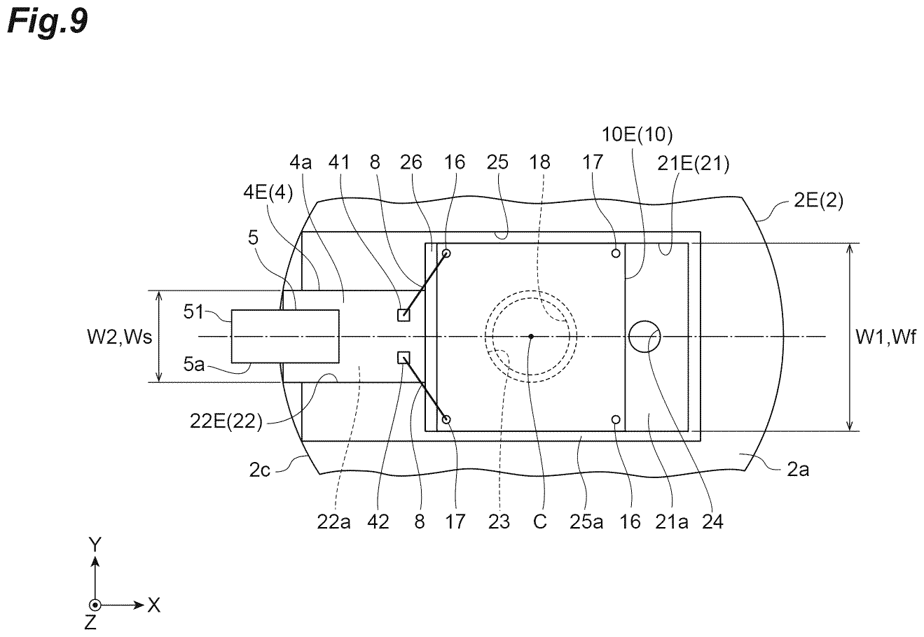

In addition, as illustrated in FIG. 9, a relationship of “Ws≤W2<Wf≤W1” may be established for the width Wf of the Fabry-Perot interference filter 10 in the Y-axis direction, the width Ws of the wiring substrate 4 in the Y-axis direction, the width W1 of the first recessed portion 21 in the Y-axis direction, and the width W2 of the second recessed portion 22 in the Y-axis direction. Even in this case, the Fabry-Perot interference filter 10 and the wiring substrate 4 can be easily and accurately positioned with respect to the support 2. In addition, the strength of the support 2 can be secured as compared with a case where the width W2 of the second recessed portion 22 is matched with the width W1 of the first recessed portion 21. In addition, it is possible to suppress stray light from entering the Fabry-Perot interference filter 10 via the second recessed portion 22 in which the wiring substrate 4 is disposed. Furthermore, portions of the support 2 on both sides of the second recessed portion 22 in the Y-axis direction come closer to the wiring substrate 4 as compared with a case where the width W2 of the second recessed portion 22 is matched with the width W1 of the first recessed portion 21, so that heat generated in the wiring substrate 4 can be efficiently released to the support 2.

The widened portion 25 may be widened at least in the Y-axis direction with respect to at least the opening of the first recessed portion 21. As an example, as illustrated in FIG. 9, the widened portion 25 may extend from the opening of the first recessed portion 21 to the opening of the second recessed portion 22, and may be widened at least in the Y-axis direction with respect to the opening of the first recessed portion 21 and the opening of the second recessed portion 22. The same applies to not only the case where the relationship of “Ws≤W2<Wf≤W1” is established (the case illustrated in FIG. 9) but also the case where the relationship of “Wf≤W1<Ws≤W2” is established (the case illustrated in FIG. 5). When the widened portion 25 extends from the opening of the first recessed portion 21 to the opening of the second recessed portion 22, it is possible to more stably support the light transmitting member 3 on the support 2 while suppressing an increase in the thickness of the Fabry-Perot interference filter 10 in the Z-axis direction that is the optical axis direction.

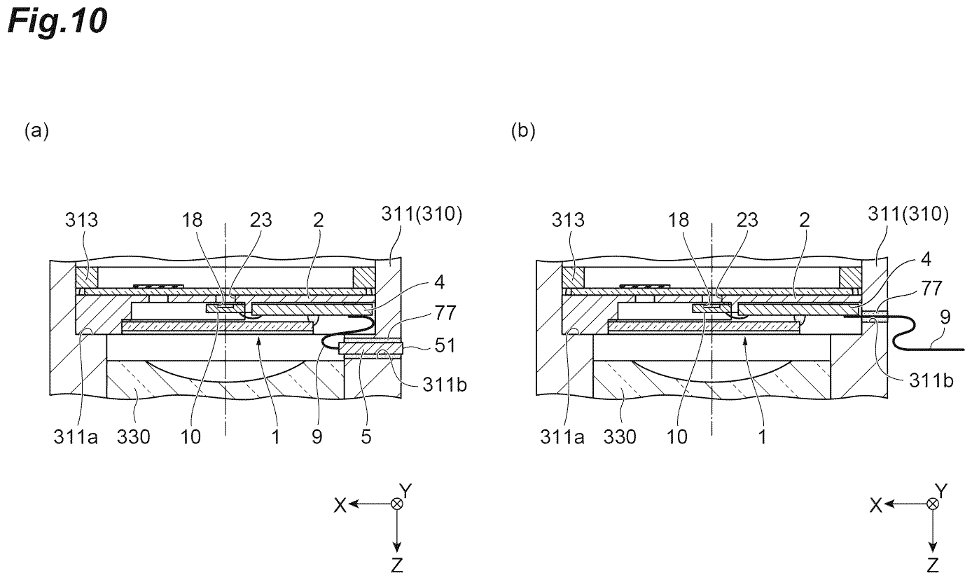

In addition, as illustrated in (a) and (b) in FIG. 10, the filter unit 1 may include a flexible wiring substrate 9 in order to be connected to wiring outside. In the example of the lens barrel illustrated in (a) in FIG. 10, one end portion of the flexible wiring substrate 9 is connected to the wiring substrate 4, and the connector 5 connected to the other end portion of the flexible wiring substrate 9 is disposed in the opening 311b of the tube 310. In this case, the adhesive member 77 is disposed between the side surface of the connector 5 and the inner surface of the opening 311b. In the example of the lens barrel illustrated in (b) in FIG. 10, one end portion of the flexible wiring substrate 9 is connected to the wiring substrate 4, and the other end portion of the flexible wiring substrate 9 is drawn out to the outside through the opening 311b of the tube 310. In this case, the adhesive member 77 is disposed between the flexible wiring substrate 9 and the inner surface of the opening 311b.

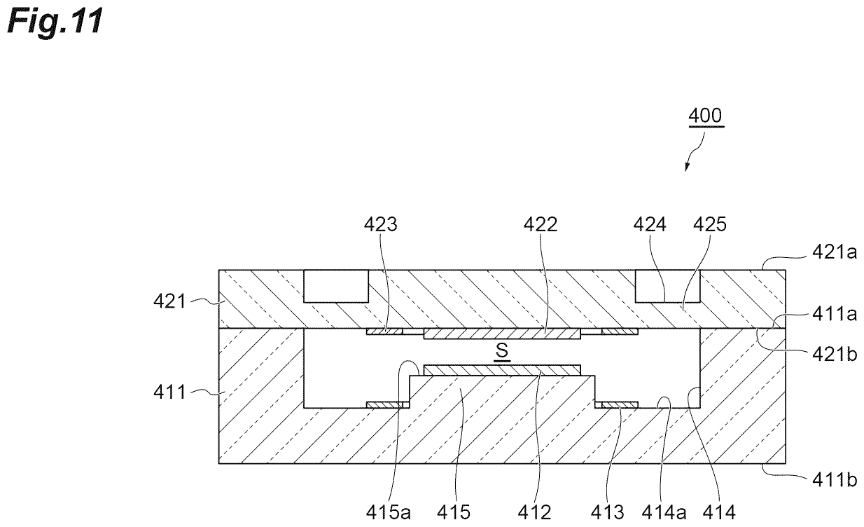

In addition, the filter unit 1 may include a Fabry-Perot interference filter as illustrated in FIG. 11. A Fabry-Perot interference filter 400 illustrated in FIG. 11 will be described. The Fabry-Perot interference filter 400 includes a substrate layer 411, a mirror section 412, and a drive electrode 413. The substrate layer 411 has a surface 411a and a surface 411b facing each other. The substrate layer 411 is formed of a light transmissive material. The mirror section 412 is, for example, a metal film, a dielectric multilayer film, or a composite film thereof. The drive electrode 413 is formed of, for example, a metal material.

The Fabry-Perot interference filter 400 further includes a substrate layer 421, a mirror section 422, and a drive electrode 423. The substrate layer 421 has a surface 421a and a surface 421b facing each other. The substrate layer 421 is formed of a light transmissive material. The mirror section 422 is, for example, a metal film, a dielectric multilayer film, or a composite film thereof. The drive electrode 423 is formed of, for example, a metal material.

A recessed portion 414 is formed on the surface 411a of the substrate layer 411. The bottom surface 414a of the recessed portion 414 is provided with a projected portion 415. With the bottom surface 414a as a reference, the height of an end surface 415a of the projected portion 415 is lower than the height of the surface 411a of the substrate layer 411. The mirror section 412 is provided on the end surface 415a of the projected portion 415. The drive electrode 413 is provided on the bottom surface 414a of the recessed portion 414 so as to surround the projected portion 415. The drive electrode 413 is electrically connected to an electrode pad (not illustrated) via, for example, wiring (not illustrated) provided on the substrate layer 411. The electrode pad is provided, for example, in a region accessible from the outside in the substrate layer 411.

The surface 421b of the substrate layer 421 is bonded to the surface 411a of the substrate layer 411 by, for example, plasma bonding or the like. A mirror section 422 and a drive electrode 423 are provided on the surface 421b of the substrate layer 421. The mirror section 422 faces the mirror section 412 via the gap S. The drive electrode 423 is provided on the surface 421b of the substrate layer 421 so as to surround the mirror section 422, and faces the drive electrode 413 via the gap S. The drive electrode 423 is electrically connected to an electrode pad (not illustrated) via, for example, wiring (not illustrated) provided on the substrate layer 421. The electrode pad is provided, for example, in a region accessible from the outside in the substrate layer 421.

On the surface 421a of the substrate layer 421, a groove 424 is formed so as to surround the mirror section 422 and the drive electrode 423 when viewed from the Z-axis direction. The groove 424 extends in an annular shape. A portion of the substrate layer 421 surrounded by the groove 424 is movable in a direction in which the pair of mirror sections 412 and 422 face each other with a portion where the groove 424 is formed as a diaphragm-shaped holding portion 425.

Note that the diaphragm-shaped holding portion 425 may be configured by forming a groove surrounding the mirror section 422 and the drive electrode 423 when viewed from the Z-axis direction on at least one of the surface 421a and the surface 421b of the substrate layer 421. A groove surrounding the mirror section 412 and the drive electrode 413 when viewed from the Z-axis direction may be formed in the substrate layer 411 to form a diaphragm-shaped holding portion in the substrate layer 411. Instead of the diaphragm-shaped holding portion, the holding portion may be constituted by a plurality of beams disposed radially.

In the Fabry-Perot interference filter 400 illustrated in FIG. 11, when a potential difference is generated between the drive electrode 413 and the drive electrode 423 by applying a voltage to the drive electrode 413 and the drive electrode 423, an electrostatic force corresponding to the potential difference is generated between the drive electrode 413 and the drive electrode 423. By generating an electrostatic force between the drive electrode 413 and the drive electrode 423, a portion of the substrate layer 421 surrounded by the groove 424 is attracted toward the substrate layer 411, and the distance between the mirror section 412 and the mirror section 422 is adjusted. As a result, light having a wavelength corresponding to the distance between the mirror section 412 and the mirror section 422 is transmitted.

In the filter unit 1, the outer edge 2E of the support 2 may have a shape other than a circular shape such as a rectangular shape when viewed from the Z-axis direction. In the filter unit 1, each of the outer edge 10E of the Fabry-Perot interference filter 10, the outer edge 4E of the wiring substrate 4, the inner edge 21E of the first recessed portion 21, and the inner edge 22E of the second recessed portion 22 may have a shape other than the rectangular shape.

In the filter unit 1, the Fabry-Perot interference filter 10 may be displaced from the center C of the support 2 when viewed from the Z-axis direction. In the filter unit 1, the mounting surface of the support 2 on which the Fabry-Perot interference filter 10 is disposed may not be the bottom surface 21a of the first recessed portion 21. In the filter unit 1, the mounting surface of the support 2 on which the wiring substrate 4 is disposed may not be the bottom surface 22a of the second recessed portion 22. In the filter unit 1, the mounting surface of the support 2 on which the Fabry-Perot interference filter 10 is disposed and the mounting surface of the support 2 on which the wiring substrate 4 is disposed may not be positioned on the same plane.

In the filter unit 1, the entire Fabry-Perot interference filter 10 may not be disposed in the first recessed portion 21. In the filter unit 1, the entire light transmitting member 3 may not be disposed in the widened portion 25. In the filter unit 1, the entire wiring substrate 4 may not be disposed in the second recessed portion 22. In the filter unit 1, the wiring substrate 4 may be attached to the housing 200 such that a part of the wiring substrate 4 is embedded in the surrounding portion 230. Note that “a part of the wiring substrate 4 is embedded in the surrounding portion 230” means that the part of the wiring substrate 4 overlaps the surrounding portion 230 when viewed from any of the X-axis direction, the Y-axis direction, and the Z-axis direction.

In the filter unit 1, the support 2 may not include the partition 26 disposed between the first recessed portion 21 and the second recessed portion 22. In the filter unit 1, the first recessed portion 21 and the second recessed portion 22 may be connected to each other. When the support 2 includes the partition 26, the partition 26 does not completely partition the first recessed portion 21 and the second recessed portion 22, but may partially partition them. When the support 2 includes the partition 26, the height of the partition 26 in the Z-axis direction is not limited to that described above. For example, the height of the partition 26 in the Z-axis direction may be higher than the height of the Fabry-Perot interference filter 10 in the Z-axis direction with the bottom surface 21a of the first recessed portion 21 as a reference. The height of the partition 26 in the Z-axis direction may be higher than the height of the wiring substrate 4 in the Z-axis direction with the bottom surface 22a of the second recessed portion 22 as a reference. The partition 26 may be formed separately from the support 2 and attached to the support 2.

In the filter unit 1, when viewed from the Z-axis direction, the “distance from the inner edge 21E of the first recessed portion 21 to the outer edge 2E of the support 2” in one direction other than the Y-axis direction may be larger than the width of the Fabry-Perot interference filter 10 in the one direction. In the filter unit 1, the “distance from the outer edge 10E of the Fabry-Perot interference filter 10 to the outer edge 2E of the support 2” in the “direction perpendicular to one side of the outer edge 10E of the Fabry-Perot interference filter 10” other than the Y-axis direction may be larger than the length of the diagonal line of the outer edge 10E of the Fabry-Perot interference filter 10, and the width of the opening 23 may be smaller than the width of the Fabry-Perot interference filter 10 in the direction perpendicular to the one side when viewed from the Z-axis direction.

In the filter unit 1, the opening 23 is formed in the support 2 as the light passing portion, but for example, a region in the opening 23 may be filled with a light transmitting material, an optical element (for example, a lens, a filter, or the like) may be disposed in the opening 23, or the like, and the light transmitting portion may be formed in the support 2 as the light passing portion. In any case, the light passing portion may pass light emitted from the Fabry-Perot interference filter 10 (or the Fabry-Perot interference filter 400) or may pass light incident on the Fabry-Perot interference filter 10 (or the Fabry-Perot interference filter 400). In the filter unit 1, the through-hole 24 may be open to the inner surface of the first recessed portion 21 and the outer surface of the support 2. In the filter unit 1, the cover 6 may not be disposed on the surface 2b of the support 2. In the filter unit 1, a light antireflection film may be formed on at least one of the surface 2b of the support 2 and the inner surface of the opening 23. As an example, when the support 2 is made of stainless steel, the light antireflection film may be formed by subjecting the surface of the support 2 to chromium plating treatment.

In the filter unit 1, the wiring substrate 4 needs to be disposed in the second recessed portion 22, but the Fabry-Perot interference filter 10 does not need to be disposed in the first recessed portion 21 as long as the Fabry-Perot interference filter is disposed on the support 2. That is, the first recessed portion 21 in which the Fabry-Perot interference filter 10 is disposed may not be formed in the support 2.

### REFERENCE SIGNS LIST

1 filter unit
2 support
2E outer edge
2b surface (outer surface)
3 light transmitting member
4 wiring substrate
7 adhesive member
10, 400 Fabry-Perot interference filter
10E outer edge
14, 15, 412, 422 mirror section
21 first recessed portion (another recessed portion)
21E inner edge
21a bottom surface (first mounting surface, inner surface)
22 second recessed portion (recessed portion)
22a bottom surface (second mounting surface)
23 opening (light passing portion)
24 through-hole
26 partition

1. A filter unit comprising:
a support having a light passing portion;
a Fabry-Perot interference filter including a pair of mirror sections facing each other in a first direction and having a variable distance from each other, the Fabry-Perot interference filter being disposed on the support so as to overlap the light passing portion when viewed from the first direction; and
a wiring substrate disposed on the support so as not to overlap the Fabry-Perot interference filter when viewed from the first direction and electrically connected to the Fabry-Perot interference filter, wherein
a recessed portion is formed in the support with the first direction as a depth direction,
the recessed portion reaches an outer edge of the support when viewed from the first direction, and
the wiring substrate is disposed in the recessed portion.

2. The filter unit according to claim 1, wherein the Fabry-Perot interference filter is positioned at a center of the support when viewed from the first direction.

3. The filter unit according to claim 2, wherein the outer edge of the support has a circular shape when viewed from the first direction.

4. The filter unit according to claim 1, wherein
another recessed portion opened on an opposite side of the light passing portion with the first direction as a depth direction is formed in the support,
the Fabry-Perot interference filter is disposed in the another recessed portion, and
each of an outer edge of the Fabry-Perot interference filter and an inner edge of the another recessed portion has a rectangular shape when viewed from the first direction.

5. The filter unit according to claim 1, wherein
the Fabry-Perot interference filter is disposed on a first mounting surface of the support,
the wiring substrate is disposed on a second mounting surface of the support, and
the first mounting surface and the second mounting surface are positioned on the same plane.

6. The filter unit according to claim 1, wherein
another recessed portion opened on an opposite side of the light passing portion with the first direction as a depth direction is formed in the support,
the Fabry-Perot interference filter is disposed in the another recessed portion, and
the support includes a partition disposed between the recessed portion and the another recessed portion.

7. The filter unit according to claim 1, further comprising:
a light transmitting member; and
an adhesive member, wherein
another recessed portion opened on an opposite side of the light passing portion with the first direction as a depth direction is formed in the support,
the Fabry-Perot interference filter is disposed in the another recessed portion,
the light transmitting member covers at least an opening of the another recessed portion, and
the adhesive member is disposed between the wiring substrate and the support and between the wiring substrate and the light transmitting member.

8. The filter unit according to claim 1, wherein
another recessed portion opened on an opposite side of the light passing portion with the first direction as a depth direction is formed in the support,
the Fabry-Perot interference filter is disposed in the another recessed portion, and
a distance from an inner edge of the another recessed portion to the outer edge of the support in one direction is larger than a width of the Fabry-Perot interference filter in the one direction when viewed from the first direction.

9. The filter unit according to claim 1, wherein
another recessed portion opened on an opposite side of the light passing portion with the first direction as a depth direction is formed in the support,
the Fabry-Perot interference filter is disposed in the another recessed portion,
the light passing portion is an opening formed in the support,
an outer edge of the Fabry-Perot interference filter has a rectangular shape when viewed from the first direction,
a distance from the outer edge of the Fabry-Perot interference filter to the outer edge of the support in a direction perpendicular to one side of the outer edge of the Fabry-Perot interference filter is larger than a length of a diagonal line of the outer edge of the Fabry-Perot interference filter when viewed from the first direction, and
a width of the opening is smaller than a width of the Fabry-Perot interference filter in the direction perpendicular to the one side when viewed from the first direction.

10. The filter unit according to claim 1, wherein
another recessed portion opened on an opposite side of the light passing portion with the first direction as a depth direction is formed in the support,
the recessed portion and the another recessed portion are arranged in a second direction perpendicular to the first direction,
the Fabry-Perot interference filter is disposed in the another recessed portion, and
when a width of the Fabry-Perot interference filter in a third direction perpendicular to both the first direction and the second direction is set as Wf, a width of the wiring substrate in the third direction is set as Ws, a width of the another recessed portion in the third direction is set as W1, and a width of the recessed portion in the third direction is set as W2, a relationship of “Wf≤W1<Ws≤W2” or a relationship of “Ws≤W2<Wf≤W1” is established.

11. The filter unit according to claim 10, wherein a relationship of “Wf=W1” is satisfied.

12. The filter unit according to claim 10, wherein a relationship of “Ws=W2” is satisfied.

13. The filter unit according to claim 1, wherein
another recessed portion opened on an opposite side of the light passing portion with the first direction as a depth direction is formed in the support,
the Fabry-Perot interference filter is disposed in the another recessed portion, and
a through-hole opened to an inner surface of the another recessed portion and an outer surface of the support is formed in the support.
